(19) United States
(12) Patent Application Publication
(10) Pub. No.: US 2014/0211891 A1
(43) Pub. Date: Jul. 31, 2014

(54) METHOD AND APPARATUS FOR CONTROLLING GAIN IN COMMUNICATON SYSTEM SUPPORTING BEAM FORMING SCHEME

(71) Applicant: Samsung Electronics Co., Ltd., Suwon-si (KR)

(72) Inventors: Jeong-Ho PARK, Seoul (KR); Won-Suk CHOI, Seongnam-si (KR); Hyun-Kyu YU, Suwon-si (KR); Jae-Weon CHO, Seongnam-si (KR)

(73) Assignee: Samsung Electronics Co., Ltd., Suwon-si (KR)

(21) Appl. No.: 14/164,731

(22) Filed: Jan. 27, 2014

(30) Foreign Application Priority Data
Jan. 25, 2013 (KR) 10-2013-0008609

(51) Int. Cl. H03G 3/20; H04B 1/16

(52) U.S. Cl. CPC H03G 3/20; H04B 1/16
USPC 375/345

(57) ABSTRACT

A signal reception apparatus in a communication system supporting a beam forming scheme is provided. The signal reception apparatus includes a Low Noise Amplifier (LNA) configured to generate a second signal by amplifying a first signal according to a first gain value, a Variable Gain Amplifier (VGA) configured to generate a third signal by amplifying the second signal according to a second gain value, and an Automatic Gain Controller (AGC) configured to control the first gain value and the second gain value by considering a plurality of beam types supported in a signal transmission apparatus.

### CROSS-REFERENCE TO RELATED APPLICATION(S)

This application claims the benefit under 35 U.S.C. §119(a) of a Korean patent application filed on Jan. 25, 2013 in the Korean Intellectual Property Office and assigned Serial number 10-2013-0008609, the entire disclosure of which is hereby incorporated by reference.

### TECHNICAL FIELD

The present disclosure relates to a method and apparatus for controlling a gain in a communication system supporting a beam forming scheme.

### BACKGROUND

To satisfy an increasing need for wireless data traffic, communication systems have been developed to support higher data rates. A communication system may improve spectral efficiency and increase channel capacity to address the increasing need, for example, by various communication schemes such as an Orthogonal Frequency Division Multiplexing (OFDM) scheme, a Multiple Input Multiple Output (MIMO) scheme, and the like.

However, it is difficult to satisfy a need for increasing data traffic in a communication system using the noted schemes for improving the spectral efficiency and increasing the channel capacity. Specially, an increase in use of a smart phone, a tablet, and the like and an increase of applications which use data traffic accelerate a need for increased data traffic.

In a communication system, there is a need for a Radio Frequency (RF) technology which may cover a relatively wide dynamic range and a RF element control scheme using an Automatic Gain Controller (AGC).

A structure of a related art communication system will be described with reference to FIG. 1.

FIG. 1 schematically illustrates a structure of a communication system according to the related art.

Referring to FIG. 1, the communication system includes a signal transmission apparatus and at least one signal reception apparatus. In FIG. 1, it will be assumed that a base station 100 is the signal transmission apparatus, a terminal 150 is the signal reception apparatus, and the communication system includes one base station and one terminal.

A relationship between the base station 100 and the terminal 150 may be expressed using various values, including P_{TX}, L, G1_{TX}, and the like. The value P_{TX} denotes transmit power of the base station 100, and may be referred to as the transmit power P_{TX}, the value L denotes path loss, and may be referred to as the path loss L, and the value G1_{TX} denotes an antenna gain of the base station 100, and may be referred to as the antenna gain G1_{TX}. The path loss L may be determined according to a distance D between the base station 100 and the terminal 150.

If a minimum path loss L_{MIN} is considered, as path loss which occurs in a case that the distance D is a minimum distance D_{MIN}, a maximum receive power P_{RX}_{_{—}}_{MAX} 101 of the terminal 100 is calculated as expressed in Equation (1).

If a maximum path loss L_{Max} is considered, as path loss which occurs in a case that the distance D is a maximum distance D_{Max}, minimum receive power P_{RX}_{_{—}}_{MIN} 103 of the terminal 100 is calculated as expressed in Equation (2).

P_{RX}_{_{—}}_{MAX}=P_{TX}+G1_{TX}_{_{—}}_{MAX}−L_{MIN} Equation (1)

P_{RX}_{_{—}}_{MIN}=P_{TX}+G1_{TX}_{_{—}}_{MIN}−L_{MAX} Equation (2)

In Equation (1), G1_{TX}_{_{—}}_{MAX} 105 denotes a maximum antenna gain used in the base station 100. In Equation (2), G1_{TX}_{_{—}}_{MIN} 110 denotes a minimum antenna gain used in the base station 100.

A dynamic range DR1 of an RF end included in the signal reception apparatus, such as the terminal 150, may be determined using a difference between the maximum receive power P_{RX}_{_{—}}_{MAX} 103 and the minimum receive power P_{RX}_{_{—}}_{MIN} 101. The dynamic range DR1 of the RF end included in the terminal 150 is calculated as Equation (3).

DR1 [dB]=P_{RX}_{_{—}}_{MAX}−P_{RX}_{_{—}}_{MIN} Equation (3)

A gain value which is used in a Low Noise Amplifier (LNA), included in a reception circuit in the terminal 150, and a gain value which is used in a Variable Gain Amplifier (VGA), included in the reception circuit in the terminal 150, should be determined by considering the dynamic range DR1 calculated in Equation (3).

The gain value of the LNA and the gain value of the VGA are determined through a control operation of the AGC, and control operations of the AGC are based on average power measured for a signal outputted from a MOdulator/DEModulator (MODEM).

A structure of a related-art communication system has been described with reference to FIG. 1, and an inner structure of a terminal in a conventional communication system will be described with reference to FIG. 2.

FIG. 2 schematically illustrates an inner structure of a terminal in a communication system according to the related art.

Referring to FIG. 2, a terminal includes an LNA 201, a mixer 203, a VGA 205, an Analog to Digital converter (A/D) 207, a MODEM 209, and an AGC 211.

The LNA 201 and the VGA 205 may operate under a control of the AGC 211, and the AGC 211 controls an operation of each of the LNA 201 and the VGA 205 by controlling a gain of each of the LNA 201 and the VGA 205. The LNA 201 amplifies a power of a signal received through an antenna by multiplying the signal received through the antenna by a preset gain value, and outputs the amplified signal to the mixer 203. The mixer 203 down converts the signal output from the LNA 201 by mixing the signal outputted from the LNA 201 with a preset frequency signal, and outputs the down converted signal to the VGA 205. The VGA 205 amplifies the down converted signal output from the mixer 203 by multiplying the down converted signal output from the mixer 203 by a preset gain value, and the amplified signal to the A/D 207. The A/D 207 generates an In phase & Quadrature phase (I/Q) signal by converting the signal outputted from the VGA 205, i.e., an analog signal to a digital signal, and outputs the I/Q signal to the MODEM 209. The MODEM 209 de-modulates the signal output from the A/D 207 using a preset de-modulation scheme, and outputs the de-modulated signal.

The signal output from the MODEM 209 is input to the AGC 211, and the AGC 211 determines a gain value of each of the LNA 201 and the VGA 205 included in the terminal using an average power of the signal output from the MODEM 209. An operation in which the AGC 211 determines the gain value used in each of the LNA 201 and the VGA 205 will be described below.

After detecting a receive power of a signal received during a previous preset time interval T_{WINDOW}, the AGC 211 maps a total range for a signal output from the VGA 205 to a total available dynamic range of the A/D 207 by controlling a gain value of each of the LNA 201 and the VGA 205. That is, the AGC 211 minimizes a quantization noise and a performance decrease due to saturation by generating a control signal which controls the gain value of each of the LNA 201 and the VGA 205, and by transmitting the control signal to each of the LNA 201 and the VGA 205. However, if the structure of the related-art terminal, as described in FIG. 2, is used in a communication system using at least two beam widths, signal distortion and a quantization error may occur.

So, there is a need for controlling a gain without signal distortion and a quantization error in a communication system using at least two beam widths.

The above information is presented as background information only to assist with an understanding of the present disclosure. No determination has been made, and no assertion is made, as to whether any of the above might be applicable as prior art with regard to the present disclosure.

### SUMMARY

Aspects of the present disclosure are to address at least the above-mentioned problems and/or disadvantages and to provide at least the advantages described below. Accordingly, an aspect of the present disclosure is to provide a method and apparatus for controlling a gain in a communication system supporting a beam forming scheme.

Another aspect of the present disclosure is to provide a method and apparatus for controlling a gain in a case that at least two beam types are used in a communication system supporting a beam forming scheme.

Another aspect of the present disclosure is to provide a method and apparatus for automatically controlling a gain corresponding to a beam type in a case that at least two beam types are used in a communication system supporting a beam forming scheme.

Another aspect of the present disclosure is to provide a method and apparatus for automatically controlling a gain by considering signal strength for an optimal beam type in a case that at least two beam types are used in a communication system supporting a beam forming scheme.

In accordance with an aspect of the present disclosure, a signal reception apparatus in a communication system supporting a beam forming scheme is provided The signal reception apparatus includes a Low Noise Amplifier (LNA) configured to generate a second signal by amplifying a first signal according to a first gain value, a Variable Gain Amplifier (VGA) configured to generate a third signal by amplifying the second signal according to a second gain value, and an Automatic Gain Controller (AGC) configured to control the first gain value and the second gain value by considering a plurality of beam types supported in a signal transmission apparatus.

In accordance with another aspect of the present disclosure, a signal reception apparatus in a communication system supporting a beam forming scheme is provided. The signal reception apparatus includes an LNA configured to generate a second signal by amplifying a first signal according to a first gain value, a mixer configured to generate a third signal by mixing the second signal with a frequency signal, a VGA configured to generate a fourth signal by amplifying the third signal according to a second gain value, an analog/digital converter configured to generate a fifth signal by digital converting the fourth signal, a MOdulator/DEModulator (MODEM) configured to generate a sixth signal by de-modulating the fifth signal using a de-modulation scheme corresponding to a modulation scheme used in a signal transmission apparatus, and an AGC configured to control the first gain value and the second gain value by considering a plurality of beam types supported in the signal transmission apparatus.

In accordance with another aspect of the present disclosure, an operation method of a signal reception apparatus in a communication system supporting a beam forming scheme is provided. The operation method includes determining a first gain value and a second gain value by considering a plurality of beam types supported in a signal transmission apparatus, generating a second signal by amplifying a first signal according to the first gain value, and generating a third signal by amplifying the second signal according to the second gain value.

In accordance with another aspect of the present disclosure, an operation method of a signal reception apparatus in a communication system supporting a beam forming scheme is provided. The operation method includes determining a first gain value and a second gain value by considering a plurality of beam types supported in a signal transmission apparatus, generating a second signal by amplifying a first signal according to the first gain value, generating a third signal by mixing the second signal with a frequency signal, generating a fourth signal by amplifying the third signal according to a second gain value, generating a fifth signal by digital converting the fourth signal, and generating a sixth signal by de-modulating the fifth signal using a de-modulation scheme corresponding to a modulation scheme used in the signal transmission apparatus.

Other aspects, advantages, and salient features of the disclosure will become apparent to those skilled in the art from the following detailed description, which, taken in conjunction with the annexed drawings, discloses various embodiments of the present disclosure.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 schematically illustrates a structure of a communication system according to the related art;

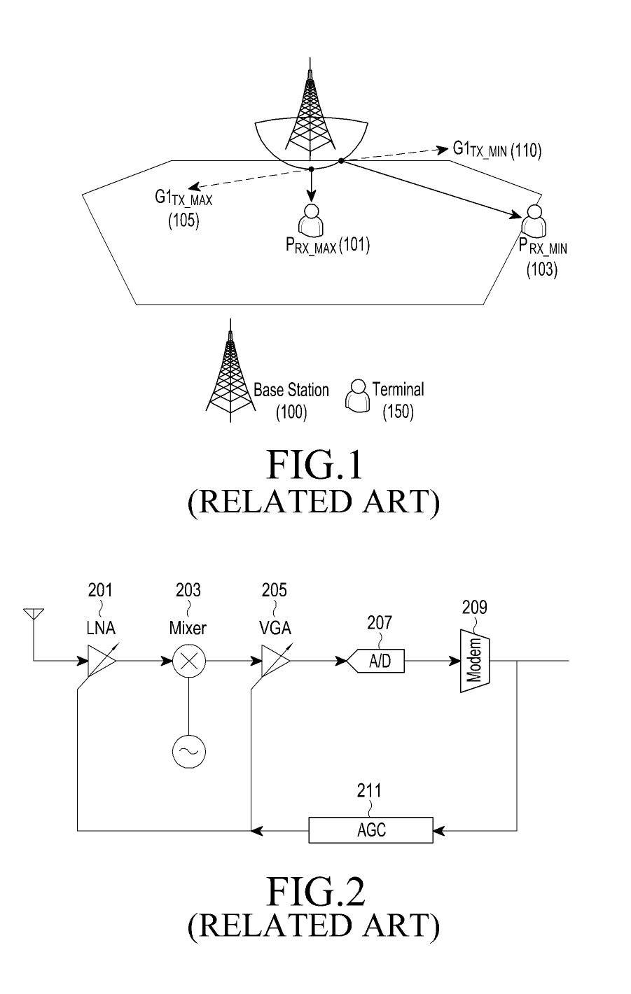

FIG. 2 schematically illustrates an inner structure of a terminal in a communication system according to the related art;

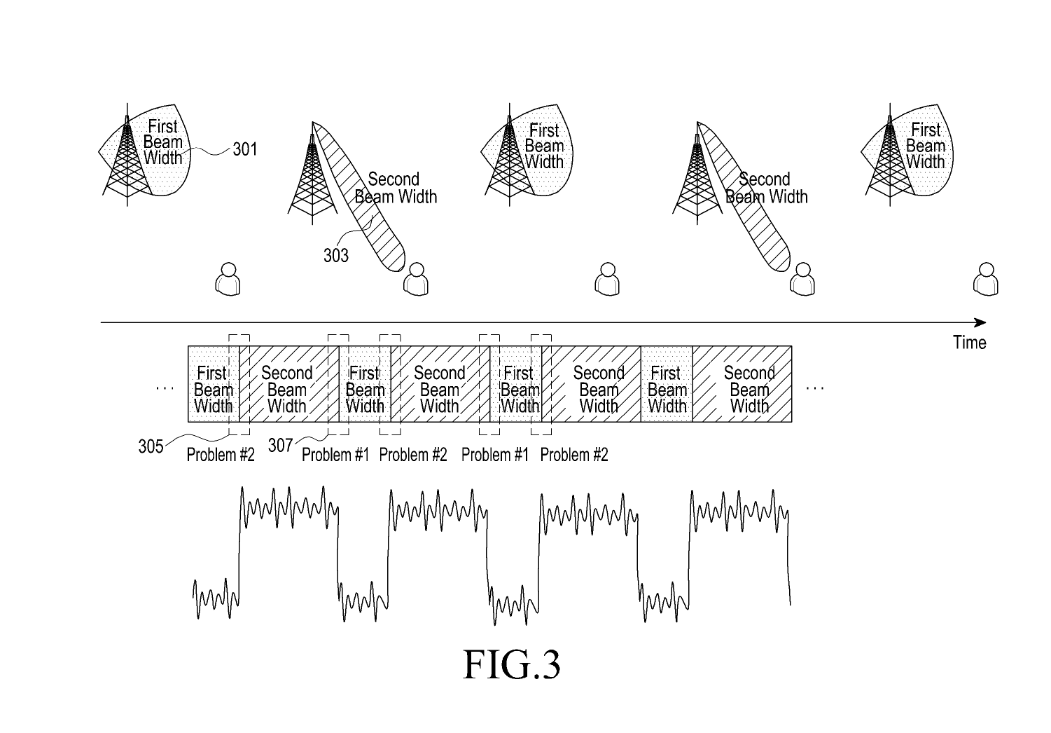

FIG. 3 schematically illustrates a structure of a communication system supporting two beam types according to an embodiment of the present disclosure;

FIG. 4 schematically illustrates a dynamic range of an Automatic Gain Controller (AGC) in a case that a terminal receives a signal to which a relatively narrow beam width is applied after receiving a signal to which a relatively wide beam width is applied in a communication system supporting a beam forming scheme according to an embodiment of the present disclosure;

FIG. 5 schematically illustrates a dynamic range of an AGC in a case that a terminal receives a signal to which a relatively wide beam width is applied after receiving a signal to which a relatively narrow beam width is applied in a communication system supporting a beam forming scheme according to an embodiment of the present disclosure;

FIG. 6 schematically illustrates an example of an inner structure of a terminal in a communication system supporting a beam forming scheme according to an embodiment of the present disclosure;

FIGS. 7A and 7B schematically illustrate another example of an inner structure of a terminal in a communication system supporting a beam forming scheme according to an embodiment of the present disclosure;

FIGS. 8A and 8B schematically illustrate still another example of an inner structure of a terminal in a communication system supporting a beam forming scheme according to an embodiment of the present disclosure;

FIG. 9 schematically illustrates an operation process of an AGC included in a terminal in a communication system supporting a beam forming scheme according to an embodiment of the present disclosure; and

FIG. 10 schematically illustrates an operation process of a terminal in a communication system supporting a beam forming scheme according to an embodiment of the present disclosure.

Throughout the drawings, like reference numerals will be understood to refer to like parts, components, and structures.

### DETAILED DESCRIPTION

The following description with reference to the accompanying drawings is provided to assist in a comprehensive understanding of various embodiments of the present disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the present disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the present disclosure. Accordingly, it should be apparent to those skilled in the art that the following description of various embodiments of the present disclosure is provided for illustration purpose only and not for the purpose of limiting the present disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

Although ordinal numbers such as “first,” “second,” and so forth will be used to describe various components, those components are not limited herein. The terms are used only for distinguishing one component from another component. For example, a first component may be referred to as a second component and likewise, a second component may also be referred to as a first component, without departing from the teaching of the inventive concept. The term “and/or” used herein includes any and all combinations of one or more of the associated listed items.

The terminology used herein is for the purpose of describing various embodiments only and is not intended to be limiting. As used herein, the singular forms are intended to include the plural forms as well, unless the context clearly indicates otherwise. It will be further understood that the terms “comprises” and/or “has,” when used in this specification, specify the presence of a stated feature, number, step, operation, component, element, or combination thereof, but do not preclude the presence or addition of one or more other features, numbers, steps, operations, components, elements, or combinations thereof.

The terms used herein, including technical and scientific terms, have the same meanings as terms that are generally understood by those skilled in the art, as long as the terms are not differently defined. It should be understood that terms defined in a generally-used dictionary have meanings coinciding with those of terms in the related technology.

An embodiment of the present disclosure provides a method and apparatus for controlling a gain in a communication system supporting a beam forming scheme.

An embodiment of the present disclosure provides a method and apparatus for controlling a gain in a case that at least two beam types are used in a communication system supporting a beam forming scheme.

An embodiment of the present disclosure provides a method and apparatus for automatically controlling a gain corresponding to a beam type in a case that at least two beam types are used in a communication system supporting a beam forming scheme.

An embodiment of the present disclosure provides a method and apparatus for automatically controlling a gain by considering signal strength for an optimal beam type in a case that at least two beam types are used in a communication system supporting a beam forming scheme.

A method and apparatus for automatically controlling a gain provides in various embodiments of the present disclosure may be applied to various communication systems such as a Long Term Evolution (LTE) mobile communication system, a LTE-Advanced (LTE-A) mobile communication system, a High Speed Downlink Packet Access (HSDPA) mobile communication system, a High Speed Uplink Packet Access (HSUPA) mobile communication system, a High Rate Packet Data (HRPD) mobile communication system proposed in a 3^{rd} Generation Project Partnership 2 (3GPP2), a Wideband Code Division Multiple Access (WCDMA) mobile communication system proposed in the 3GPP2, a Code Division Multiple Access (CDMA) mobile communication system proposed in the 3GPP2, an Institute of Electrical and Electronics Engineers (IEEE) mobile communication system, an Evolved Packet System (EPS), a Mobile Internet Protocol (Mobile IP) system, and/or the like.

In an embodiment of the present disclosure, it will be assumed that the beam type is determined based on at least one of a beam width, a beam direction, and a combination of the beam width and the beam direction. That is, the beam type may be determined by considering the beam width, or the beam direction, or both the beam width and the beam direction.

In an embodiment of the present disclosure, it will be assumed that a signal transmission apparatus is a base station, and a signal reception apparatus is a terminal. However, the present disclosure is not limited thereto, and the signal transmission apparatus may be any apparatus of a communication system that may transmit a signal, and the signal reception apparatus may be any apparatus of a communication system that may receive a signal.

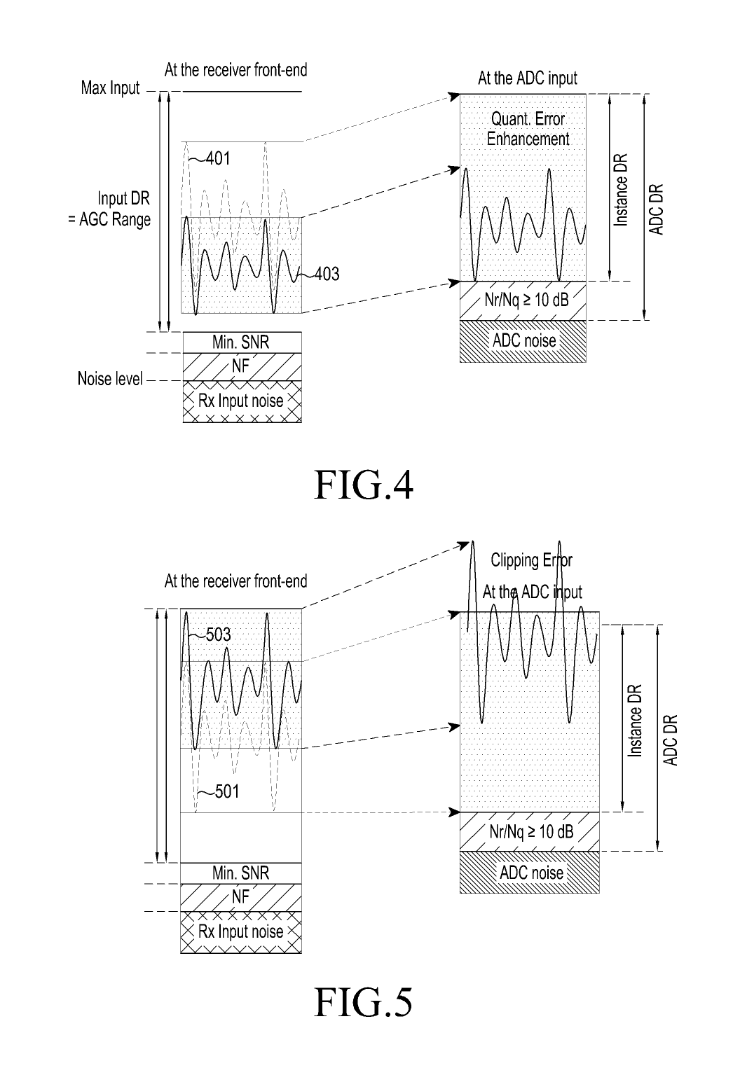

A structure of a communication system supporting two beam types according to an embodiment of the present disclosure will be described with reference to FIG. 3.

FIG. 3 schematically illustrates a structure of a communication system supporting two beam types according to an embodiment of the present disclosure.

Referring to FIG. 3, it will be noted that a beam type is determined by considering a beam width, and a communication system uses two beam widths. However, the present disclosure is not limited thereto, and the communication system may use any suitable number of beam widths. As illustrated in FIG. 3, for example, the communication system supports two beam widths including a first beam width 301 and a second beam width 303. The first beam width 301 is applied to channels, such as a synchronization channel, a broadcast channel, and any other similar and/or suitable channels, which all signal reception apparatuses, e.g., terminals, which are located in service coverage of a signal transmission apparatus, e.g., a base station, should receive. The second beam width 303 may be applied to a channel, e.g., a data channel or any other similar channel, which supports a relatively high data rate, and which is more narrow than the first beam width 301. A maximum antenna gain for the first beam width 301 is less than a maximum antenna gain for the second beam width 303. It will be assumed that an antenna gain includes a beam forming gain. A maximum antenna gain for each beam width is acquired in a direction where a signal reception apparatus detects a maximum receive signal strength from among a plurality of directions in which the base station operates, and antenna gains acquired in the plurality of directions may be different from one another.

Meanwhile, if each beam width is used, a minimum antenna gain may be acquired in a specific direction from among the plurality of directions, and a detailed description will be followed.

A maximum antenna gain of the first beam width 301 is acquired if the first beam width 301 is configured to be G1_{TX}_{_{—}}_{MAX}, and a minimum antenna gain of the first beam width 301 is acquired if the first beam width 301 is configured to be G1_{TX}_{_{—}}_{MIN}. A maximum antenna gain of the second beam width 303 is acquired if the second beam width 303 is configured to be G2_{TX}_{_{—}}_{MAX}, and a minimum antenna gain of the second beam width 303 is acquired if the second beam width 303 is configured to be G2_{TX}_{_{—}}_{MIN}.

In this case, for detecting a receive power of a terminal, both a maximum antenna gain per beam width, G1_{TX}_{_{—}}_{MAX} and G2_{TX}_{_{—}}_{MAX}, used in a base station, and a minimum antenna gain per beam width, G1_{TX}_{_{—}}_{MIN}, G2_{TX}_{_{—}}_{MIN}, used in the base station, are considered.

If the second beam width 303 is used, a maximum antenna gain G2_{TX}_{_{—}}_{MAX} may be expressed as Equation (4).

G2_{TX}_{_{—}}_{MAX}=G1_{TX}_{_{—}}_{MAX}+BF_{TX}_{_{—}}_{MAX} Equation (4)

In Equation (4), BF_{TX}_{_{—}}_{MAX} denotes a difference between a maximum antenna gain which may be acquired if the first beam width 301 is used and a maximum antenna gain which may be acquired if the second beam width 303 is used.

So, in the case where the base station operates two beam widths, i.e., the first beam width 301 and the second beam width 303, the terminal may acquire the maximum receive power in a case where both the terminal acquires the maximum antenna gain G2_{TX}_{_{—}}_{MAX} and path loss, according to a distance between the base station and the terminal, is minimized.

Equation (5) expresses the maximum receive power, i.e., the maximum receive power which is acquired in a case where both the terminal acquires the maximum antenna gain G2_{TX}_{_{—}}_{MAX}, and the path loss, according to the distance between the base station and the terminal, is minimized if the second beam width 303 is used.

P_{RX}_{_{—}}_{MAX}=P_{TX}+G2_{TX}_{_{—}}_{MAX}−L_{MIN} Equation (5)

In Equation (5), P_{TX} denotes a transmit power used in the base station, L_{MIN} denotes a minimum path loss according to the distance between the base station and the terminal, and P_{RX}_{_{—}}_{MAX} denotes a maximum receive power detected in the terminal.

The minimum receive power of the terminal denotes a receive power which is measured if both the minimum antenna gain G1_{TX}_{_{—}}_{MIN} is acquired when the first beam width 301 is used, and the path loss for the distance between the base station and the terminal is maximized.

Equation (6) expresses the minimum receive power which is measured if both the minimum antenna gain G1_{TX}_{_{—}}_{MIN} is acquired when the first beam width 301 is used, and the path loss for the distance between the signal transmission apparatus and the signal reception apparatus is maximized.

P_{RX}_{_{—}}_{MIN}=P_{TX}+G1_{TX}_{_{—}}_{MIN}−L_{MAX} Equation (6)

In Equation (6), P_{TX} denotes a transmit power used in the base station, L_{MAX} denotes a maximum path loss according to the distance between the base station and the terminal, and P_{RX}_{_{—}}_{MIN} denotes a minimum receive power detected in the terminal.

A dynamic range DR2, of the terminal, is a value between the maximum receive power and the minimum receive power, and may be expressed as Equation (7).

DR2 [dB]=P_{RX}_{_{—}}_{MAX}−P_{RX}_{_{—}}_{MIN}=DR1+BF_{TX}_{_{—}}_{MAX} Equation (7)

If a terminal operates a plurality of beam widths, the terminal receives a signal having a signal strength that is different according to a beam width, so a dynamic range in a case where the terminal operating the plurality of beam widths increases compared to a case where the base station operates a single beam width.

Received signal strength may change according to a beam width even though path loss does not change. For example, in FIG. 3, there are two cases, a first case 305, in which the terminal receives a signal to which the second beam width 303, which is a relatively narrow beam width, is applied after receiving a signal to which the first beam width 301, which is a relatively wide beam width, is applied, and a second case 307, in which the terminal receives the signal to which the first beam width 301, which is the relatively wide beam width, is applied after receiving the signal to which the second beam width 303, which is the relatively narrow beam width, is applied.

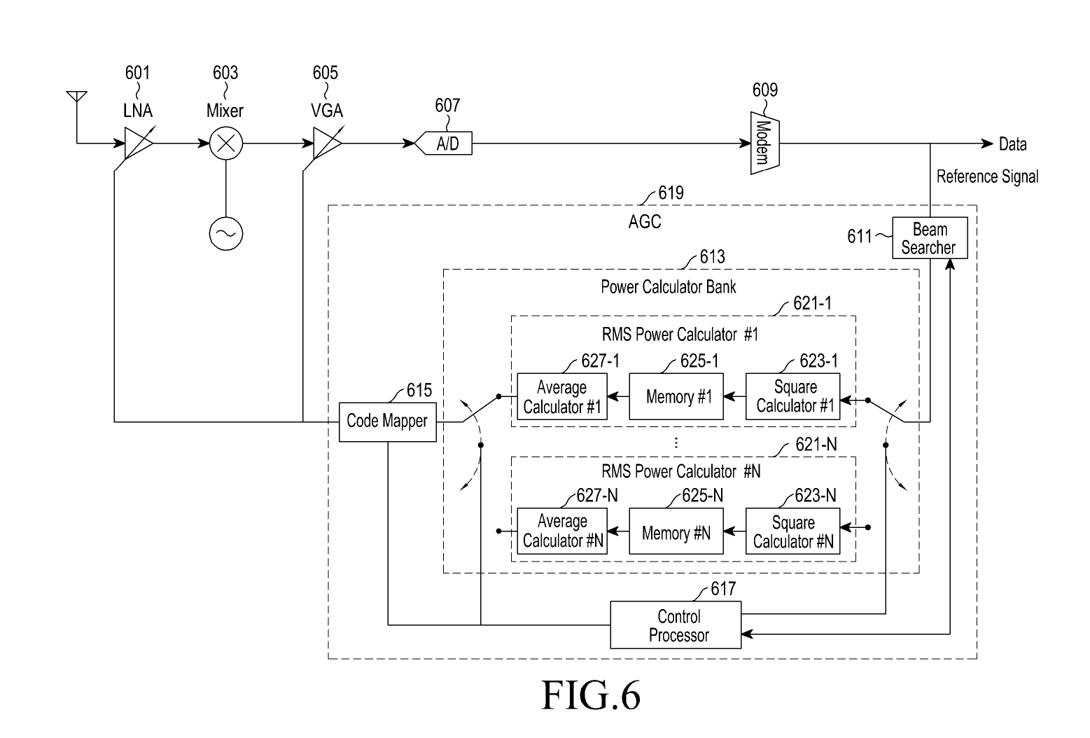

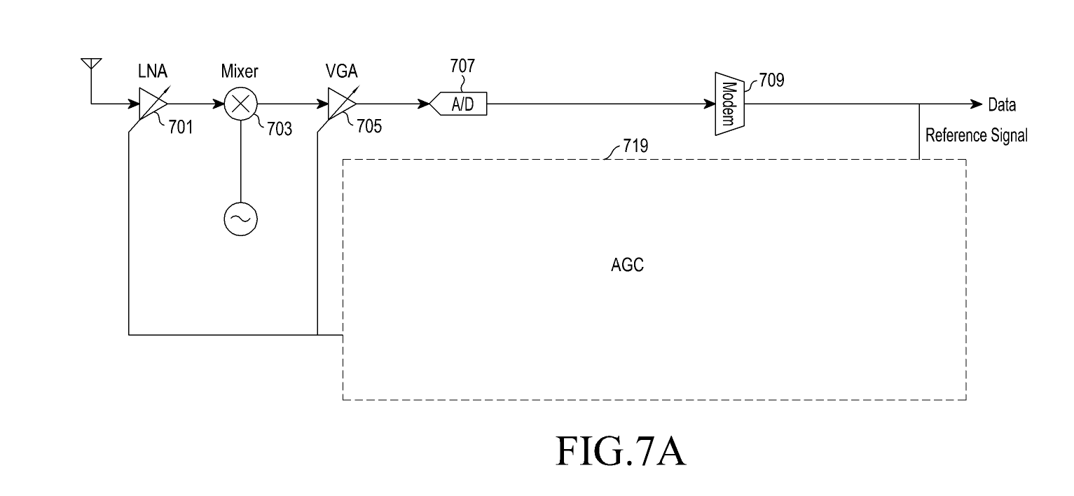

A dynamic range of an Automatic Gain Controller (AGC), in a case where a terminal receives a signal to which a relatively narrow beam width is applied after receiving a signal to which a relatively wide beam width is applied, will be described with reference to FIG. 4. A dynamic range of the AGC, in a case where the terminal receives the signal to which the relatively wide beam width is applied after receiving the signal to which the relatively narrow beam width is applied, will be described with reference to FIG. 5.

Firstly, a dynamic range of an AGC in a case where a terminal receives a signal to which a relatively narrow beam width is applied after receiving a signal to which a relatively wide beam width is applied in a communication system supporting a beam forming scheme according to an embodiment of the present disclosure will be described with reference to FIG. 4.

FIG. 4 schematically illustrates a dynamic range of an AGC in a case where a terminal receives a signal to which a relatively narrow beam width is applied after receiving a signal to which a relatively wide beam width is applied in a communication system supporting a beam forming scheme according to an embodiment of the present disclosure.

Referring to FIG. 4, a relatively wide beam width is referred to as a ‘first beam width’, and a relatively narrow beam width is referred to as a ‘second beam width’, wherein the first beam width is wider relative to the second beam width.

As illustrated in FIG. 4, an AGC determines a gain value of a Low Noise Amplifier (LNA) and a gain value of a Variable Gain Amplifier (VGA) according to an average receive power of a received signal to which the second beam width is applied, and appropriately maps a range of a signal, which is controlled according to both the determined gain value of the LNA and the determined gain value of the VGA, to a dynamic range of the AGC. If a signal to which the first beam width is applied starts to be received, a receive power of a signal 403, to which the first beam width is applied and which is detected in a front end of a terminal, becomes lower than a receive power level of a receive signal 401, which is detected in the front end of the terminal in a case where a signal, to which the second beam width is applied, is received.

That is, if the second beam width is used, an antenna gain of a base station decreases and receive power of a terminal decreases. On the other hand, if the gain values calculated for the second beam width are applied when the signal to which the first beam width is applied is received, a signal input to an AGC has a receive power level having a range narrower than a dynamic range of the AGC, so a quantization error may occur.

The dynamic range of an AGC in the case where the terminal receives the signal to which the relatively narrow beam width is applied after receiving the signal to which the relatively wide beam width is applied in the communication system supporting the beam forming scheme according to an embodiment of the present disclosure has been described with reference to FIG. 4, as noted above. The dynamic range of the AGC in the case where the terminal receives the signal to which the relatively wide beam width is applied after receiving the signal to which a relatively narrow beam width is applied in the communication system supporting the beam forming scheme according to an embodiment of the present disclosure will be described with reference to FIG. 5, as noted above.

FIG. 5 schematically illustrates a dynamic range of an AGC in a case that a terminal receives a signal to which a relatively wide beam width is applied after receiving a signal to which a relatively narrow beam width is applied in a communication system supporting a beam forming scheme according to an embodiment of the present disclosure.

Prior to a description of FIG. 5, a relatively wide beam width is referred to as a ‘first beam width’, and a relatively narrow beam width is referred to as a ‘second beam width’, wherein the first beam width is wide relative to the second beam width.

Referring to FIG. 5, an AGC determines a gain value of an LNA and a gain value of a VGA according to an average receive power of a received signal to which the first beam width is applied, and the AGC appropriately maps a range of a signal, which is controlled according to both the determined gain value of the LNA and the determined gain value of the VGA, to a dynamic range of the AGC.

If a signal to which the second beam width is applied starts to be received, a receive power of a signal 503, to which the second beam width is applied and which is detected in a front end of a terminal, becomes greater than a receive power of a receive signal 501, which is detected in the front of the terminal, in a case where the signal to which the second beam width is applied is received.

That is, if the second beam width is applied, an antenna gain of a base station increases and receive power of a terminal increases. On the other hand, if the gain values calculated for the first beam width are applied when the signal to which the second beam width is received, a signal inputted to an AGC has a receive power level with a range wider than a dynamic range of the AGC, so a clipping error may occur.

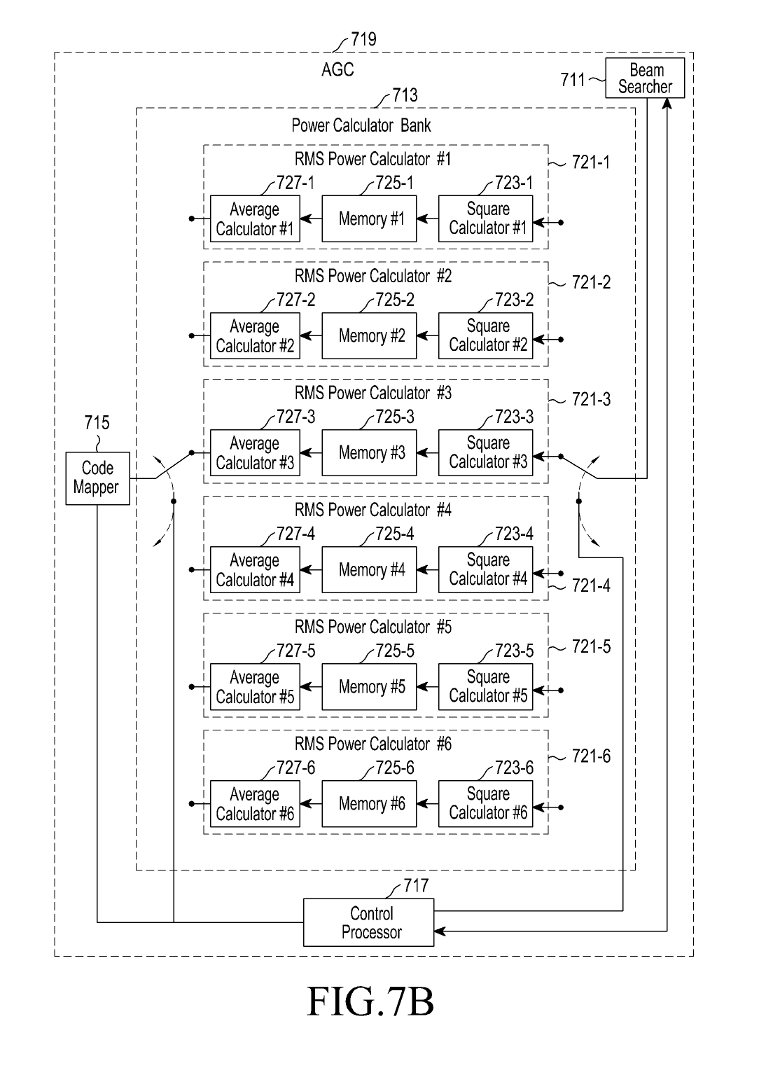

A dynamic range of an AGC, in a case where a terminal receives a signal to which a relatively wide beam width is applied, after receiving a signal to which a relatively narrow beam width is applied, in a communication system supporting a beam forming scheme according to an embodiment of the present disclosure has been described with reference to FIG. 5, and an example of an inner structure of a terminal in a communication system supporting a beam forming scheme according to an embodiment of the present disclosure will be described with reference to FIG. 6.

FIG. 6 schematically illustrates an example of an inner structure of a terminal in a communication system supporting a beam forming scheme according to an embodiment of the present disclosure.

Referring to FIG. 6, a terminal includes an LNA 601, a mixer 603, a VGA 605, an Analog to Digital converter (A/D) 607, a MOdulator/DEModulator (MODEM) 709, and an AGC 619.

A signal received through an antenna is inputted to the LNA 601, the LNA 601 amplifies the signal received through the antenna according to a preset gain value, and outputs the amplified signal to the mixer 603. The mixer 603 down converts the signal output from the LNA 601 by mixing the amplified signal output from the LNA 601 with a preset frequency signal, and the mixer 603 outputs the down converted signal to the VGA 605. The VGA 605 amplifies the signal output from the mixer 603 according to another preset gain value, and outputs the amplified signal to the A/D 607. The A/D 607 generates an In phase & Quadrature phase (I/Q) signal by converting the signal output from the VGA 605, i.e., an analog signal, into a digital signal, and the A/D 607 outputs the I/Q signal to the MODEM 609. The MODEM 609 de-modulates the signal output from the A/D 607 using a preset de-modulation scheme, and outputs the de-modulated signal. The de-modulation scheme is determined according to a modulation scheme used in the base station. The AGC 619 performs an operation of controlling both the gain value of the LNA 601 and the gain value of the VGA 605. The AGC 619 may control both the gain value of the LNA 601 and the gain value of the VGA 605 according to a beam type used in the base station, may output a control signal for controlling the gain value of the LNA 601 to the LNA 601, and may output a control signal for controlling the gain value of the VGA 605 to the VGA 605.

An operation of storing information on a beam type used in the terminal and an operation of controlling both the gain value of the LNA 601 and the gain value of the VGA 605 in the AGC 619 will be described below.

The AGC 619 includes a beam searcher 611, a power calculator bank 613, a code mapper 615, and a control processor 617.

The power calculator bank 613 includes a plurality of Root Mean Square (RMS) power calculators, e.g., N RMS power calculators for storing instantaneous power measured per beam type. That is, the power calculator bank 613 includes an RMS power calculator #1 621-1 to a RMS power calculator #N 621-N. The number, N, of the RMS power calculators included in the power calculator bank 613 may be determined according to the number of beam types which the base station may operate, use, and/or apply. That is, the number, N, of the RMS power calculators is equal to the number of the beam types which the base station may operate.

The beam searcher 611 measures instantaneous power of a reference signal output from the MODEM 609 according to a beam type that is applied to a currently received signal. The beam type may become different according to a beam width and a beam direction. In other words, respective beam types may be different from each other according to respective beam widths and beam directions. The beam searcher 611 outputs the measured instantaneous power of the reference signal and related beam information to the control processor 617. The control processor 617 detects information on a plurality of beam types operated in the base station, information on a beam gain per beam type, information on a time interval used per beam type, information on a channel used per beam type, and information on the like, from a broadcast channel which the base station broadcasts. In an embodiment of the present disclosure, the control processor 617 detects the information on the plurality of beam types operated in the base station, the information on the beam gain per beam type, the information on the time interval used per beam type, the information on the channel used per beam type, and the information on like from the broadcast channel. However, it will be understood by those of ordinary skill in the art that the control processor 617 may detect the information on the plurality of beam types operated in the base station, the information on the beam gain per beam type, the information on the time interval used per beam type, the information on the channel used per beam type, and the information on like from a channel different from the broadcast channel, from a message, and/or from any suitable source of such information.

The control processor 617 determines an RMS power calculator, in which a power value output from the beam searcher 611 will be stored, from among the RMS power calculator #1 621-1 to the RMS power calculator #N 621-N, according to the measured result output from the beam searcher 611. The control processor 617 selects a RMS power calculator, which will be used for determining the gain value of the LNA 601 and the gain value of the VGA 605, from among the RMS power calculator #1 621-1 to the RMS power calculator #N 621-N, based on the beam information.

The power calculator bank 613 includes N RMS power calculators, i.e., the RMS power calculator #1 621-1 to the RMS power calculator #N 621-N. Each of the RMS power calculator #1 621-1 to the RMS power calculator #N 621-N stores instantaneous power by calculating an average power per related beam type. The beam type may be classified based on at least one of a beam width and a beam direction. The number, N, of the RMS power calculators included in the power calculator bank 613 may be determined according to the number of beam types which the base station may operate. The number, N, of the RMS power calculators is equal to the number of the beam types that the base station may operate.

Meanwhile, each of the RMS power calculator #1 621-1 to the RMS power calculator #N 621-N includes a square calculator, a memory, and an average calculator. That is, the RMS power calculator #1 621-1 includes a square calculator #1 623-1, a memory #1 625-1, and an average calculator #1 627-1. In this way, the RMS power calculator #N 621-N, as the last RMS power calculator, includes a square calculator #N 623-N, a memory #N 625-N, and an average calculator #N 627-N.

Firstly, the RMS power calculator #1 621-1 will be described below.

The square calculator #1 623-1 calculates an instantaneous power value by squaring a signal strength of the signal output from the MODEM 609, and outputs the instantaneous power value to the memory #1 625-1. The memory #1 625-1 stores the instantaneous power value output from the square calculator #1 623-1. The average calculator #1 627-1 calculates an average power of the instantaneous power values stored during a preset time interval, e.g., T_{WINDOW}.

The RMS power calculator #N 621-N, as the last RMS power calculator, will be described below.

The square calculator #N 623-N calculates an instantaneous power value by squaring a signal strength of the signal output from the MODEM 609, and outputs the instantaneous power value to the memory #N 625-N. The memory #N 625-N stores the instantaneous power value output from the square calculator #N 623-N. The average calculator #N 627-N calculates an average power of the instantaneous power values stored during the preset time interval T_{WINDOW}.

The code mapper 615 determines both the gain value of the LNA 601 and the gain value of the VGC 619 based on the average power calculated, in the average calculator #1 627-1 to the average calculator #N 627-N, according to a timing point determined by the control processor 617. The code mapper 615 generates a code value related to each of the gain value of the LNA 601 and the gain value of the VGC 619, and outputs the generated code value to the LNA 601 and the VGC 619.

Although the LNA 601, the mixer 603, the VGA 605, the A/D 607, the MODEM 609, and the AGC 619, are illustrated in the terminal in FIG. 6 as separate units, it is to be understood that such a configuration is merely for convenience of description. In other words, two or more of the LNA 601, the mixer 603, the VGA 605, the A/D 607, the MODEM 609, and the AGC 619 may be incorporated into a single unit. Further, locations of LNA 601, the mixer 603, the VGA 605, the A/D 607, the MODEM 609, and the AGC 619 may be changed, and specific units among these units may be omitted. Although N RMS power calculators, i.e., the RMS power calculator #1 621-1 to the RMS power calculator #N 621-N, are illustrated in the power calculator bank 613, in FIG. 6, as separate units, it is to be understood that such a configuration is merely for convenience of description. In other words, two or more of the RMS power calculator #1 621-1 to the RMS power calculator #N 621-N may be incorporated into a single unit. Although a square calculator, a memory, and an average calculator are illustrated in each of the RMS power calculator #1 621-1 to the RMS power calculator #N 621-N, in FIG. 6, as separate units, it is to be understood that such a configuration is merely for convenience of description. In other words, two or more of the square calculator, the memory, and the average calculator may be incorporated into a single unit.

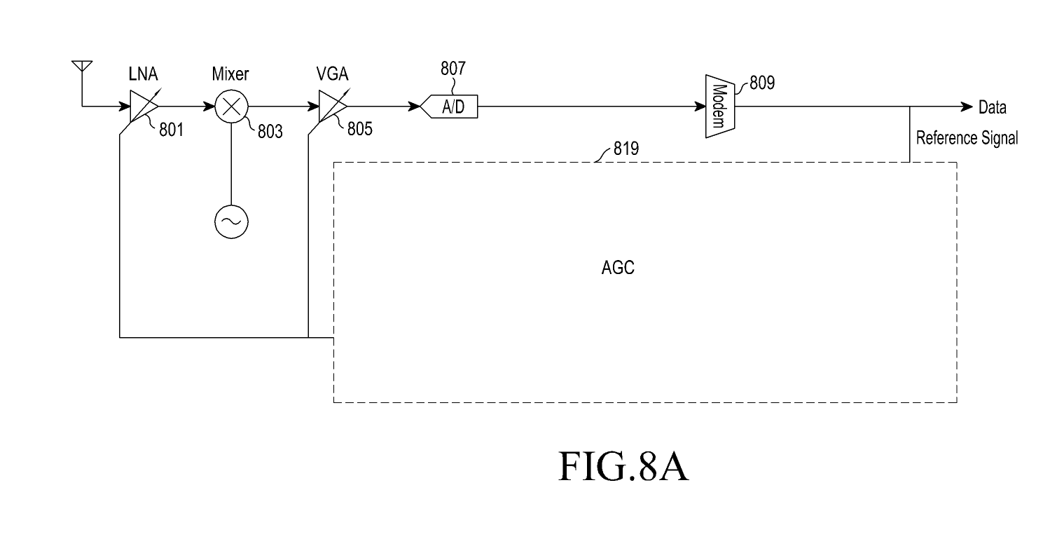

An example of an inner structure of a terminal in a communication system supporting a beam forming scheme according to an embodiment of the present disclosure has been described with reference to FIG. 6, and another example of an inner structure of a terminal in a communication system supporting a beam forming scheme according to an embodiment of the present disclosure will be described with reference to FIGS. 7A and 7B.

FIGS. 7A and 7B schematically illustrate another example of an inner structure of a terminal in a communication system supporting a beam forming scheme according to an embodiment of the present disclosure.

Referring to FIGS. 7A to 7B, a terminal includes an LNA 701, a mixer 703, a VGA 705, an A/D 707, a MODEM 709, and an AGC 719.

The internal structure of the terminal illustrated in FIGS. 7A to 7B corresponds an internal structure of a terminal in a case where a base station supports six beam types, and the six beam types are generated by considering two beam widths, i.e., a first beam width and a second beam width, and four beam directions, i.e., a first beam direction, a second beam direction, a third beam direction, and a fourth beam direction. That is, the base station supports a first beam type which is generated by considering the first beam width and the first beam direction, a second beam type which is generated by considering the first beam width and the second beam direction, a third beam type which is generated by considering the second beam width and the first beam direction, a fourth beam type which is generated by considering the second beam width and the second beam direction, a fifth beam type which is generated by considering the second beam width and the third beam direction, and a sixth beam type which is generated by considering the second beam width and the fourth beam direction. However, the present disclosure is not limited thereto, and an the internal structure of the terminal of the present disclosure may correspond to a base station that supports any suitable and/or similar number of beam types.

A signal received through an antenna is input to the LNA 701, the LNA 701 amplifies the signal received through the antenna according to a preset gain value, and outputs the amplified signal to the mixer 703. The mixer 703 down converts the signal output from the LNA 701 by mixing the amplified signal output from the LNA 701 with a preset frequency signal, and outputs the down converted signal to the VGA 705. The VGA 705 amplifies the signal output from the mixer 703 according to another preset gain value, and outputs the amplified signal to the A/D 707. The A/D 707 generates an I/Q signal by converting the signal output from the VGA 705, i.e., an analog signal, into a digital signal, and the A/D/707 outputs the I/Q signal to the MODEM 709. The MODEM 709 de-modulates the signal output from the A/D 707 using a preset de-modulation scheme, and outputs the de-modulated signal. The de-modulation scheme is determined according to a modulation scheme used in the base station.

The AGC 719 performs an operation of controlling both the gain value of the LNA 701 and the gain value of the VGA 705. The AGC 719 may control both the gain value of the LNA 701 and the gain value of the VGA 705 according to a beam type used in the base station, outputs a control signal for controlling the gain value of the LNA 701 to the LNA 701, and outputs a control signal for controlling the gain value of the VGA 705 to the VGA 705.

An operation of storing information on a beam type used in the terminal and an operation of controlling both the gain value of the LNA 701 and the gain value of the VGA 705 in the AGC 719 will be described below.

The AGC 719 includes a beam searcher 711, a power calculator bank 713, a control processor 717, and a code mapper 715.

The power calculator bank 713 includes a plurality of RMS power calculators, e.g., six RMS power calculators, for storing instantaneous power measured per beam type. That is, the power calculator bank 713 includes an RMS power calculator #1 721-1 to an RMS power calculator #6 721-6. The number of the RMS power calculators included in the power calculator bank 713 may be determined according to the number of beam types which the base station may operate. That is, the number of the RMS power calculators is equal to the number of the beam types that the base station may operate, e.g., ‘6’.

The beam searcher 711 measures an instantaneous power of a reference signal output from the MODEM 709 according to a beam type that is applied to a currently received signal. The beam type may become different according to a beam width and a beam direction. In other words, respective beam types may be different from each other according to respective beam widths and beam directions. The beam searcher 711 outputs the measured instantaneous power for the reference signal and related beam information to the control processor 717. The control processor 717 detects information on a plurality of beam types operated in the base station, information on a beam gain per beam type, information on a time interval used per beam type, information on a channel used per beam type, and information on the like, from a broadcast channel which the base station broadcasts.

In an embodiment of the present disclosure, the control processor 717 detects the information on the plurality of beam types operated in the base station, the information on the beam gain per beam type, the information on the time interval used per beam type, the information on the channel used per beam type, and the like from the broadcast channel. However, it will be understood by those of ordinary skill in the art that the control processor 717 may detect the information on the plurality of beam types operated in the base station, the information on the beam gain per beam type, the information on the time interval used per beam type, the information on the channel used per beam type, and the like from a channel different from the broadcast channel, from a message, and/or from any suitable and/or similar source. The control processor 717 determines an RMS power calculator, in which a power value output from the beam searcher 711 will be stored, from among the RMS power calculator #1 721-1 to the RMS power calculator #N 721-N, according to the measured result output from the beam searcher 711. The control processor 717 selects an RMS power calculator, which will be used for determining the gain value of the LNA 701 and the gain value of the VGA 705, from among the RMS power calculator #1 721-1 to the RMS power calculator #N 721-N, based on the beam information.

The power calculator bank 713 includes six RMS power calculators, i.e., the RMS power calculator #1 721-1 to the RMS power calculator #6 721-6. Each of the RMS power calculator #1 721-1 to the RMS power calculator #6 721-6 stores an instantaneous power by calculating an average power per related beam type. The beam type may be classified based on at least one of a beam width and a beam direction. The number of the RMS power calculators included in the power calculator bank 713 may be determined according to the number of beam types which the base station may operate. The number of the RMS power calculators, 6, is equal to the number of the beam types that the base station may operate.

Meanwhile, each of the RMS power calculator #1 721-1 to the RMS power calculator #6 721-6 includes a square calculator, a memory, and an average calculator. That is, the RMS power calculator #1 721-1 includes a square calculator #1 723-1, a memory #1 725-1, and an average calculator #1 727-1, the RMS power calculator #2 721-2 includes a square calculator #2 723-2, a memory #2 725-2, and an average calculator #2 727-2, the RMS power calculator #3 721-3 includes a square calculator #3 723-3, a memory #3 725-3, and an average calculator #3 727-3, the RMS power calculator #4 721-4 includes a square calculator #4 723-4, a memory #4 725-4, and an average calculator #4 727-4, the RMS power calculator #5 721-5 includes a square calculator #5 723-5, a memory #5 725-5, and an average calculator #5 727-5, and the RMS power calculator #6 721-6 includes a square calculator #6 723-6, a memory #6 725-6, and an average calculator #6 727-6.

Firstly, the RMS power calculator #1 721-1 will be described below.

The square calculator #1 723-1 calculates an instantaneous power value by squaring a signal strength of the signal output from the MODEM 709, and outputs the instantaneous power value to the memory #1 725-1. The memory #1 725-1 stores the instantaneous power value output from the square calculator #1 723-1. The average calculator #1 727-1 calculates an average power of the instantaneous power values stored during a preset time interval, e.g., T_{WINDOW}.

The RMS power calculator #6 721-6, as the last RMS power calculator, will be described below.

The square calculator #6 723-6 calculates an instantaneous power value by squaring a signal strength of the signal output from the MODEM 709, and outputs the instantaneous power value to the memory #6 725-6. The memory #6 725-6 stores the instantaneous power value output from the square calculator #6 723-6. The average calculator #6 727-6 calculates an average power of the instantaneous power values stored during the preset time interval, e.g., T_{WINDOW}.

The code mapper 715 determines the gain value of the LNA 701 and the gain value of the VGA 705 based on the average power calculated, in the average calculator #1 727-1 to the average calculator #6 727-6, corresponding to a timing point determined by the control processor 717. The code mapper 715 generates a code value related to each of the gain value of the LNA 701 and the gain value of the VGA 705, and outputs the generated code value to the LNA 701 and the VGA 705.

In FIGS. 7A to 7B, it will be noted that the terminal is illustrated such that the power calculator bank 713 includes an RMS power calculator for each of beam types supported in the base station.

Although the LNA 701, the mixer 703, the VGA 705, the A/D 707, the MODEM 709, and the AGC 719 are illustrated in the terminal in FIGS. 7A to 7B as separate units, it is to be understood that such a configuration is merely for convenience of description. In other words, two or more of the LNA 701, the mixer 703, the VGA 705, the A/D 707, the MODEM 709, and the AGC 719 may be incorporated into a single unit. Further, locations of LNA 701, the mixer 703, the VGA 705, the A/D 707, the MODEM 709, and the AGC 719 may be changed, and specific units among these units may be omitted. Although six RMS power calculators, i.e., the RMS power calculator #1 721-1 to the RMS power calculator #6 721-6, are illustrated in the power calculator bank 713 in FIGS. 7A to 7B as separate units, it is to be understood that such a configuration is merely for convenience of description. In other words, two or more of the RMS power calculator #1 721-1 to the RMS power calculator #6 721-6 may be incorporated into a single unit. Although a square calculator, a memory, and an average calculator are illustrated in each of the RMS power calculator #1 to the RMS power calculator #6 in FIGS. 7A to 7B as separate units, it is to be understood that such a configuration is merely for convenience of description. In other words, two or more of the square calculator, the memory, and the average calculator may be incorporated into a single unit.

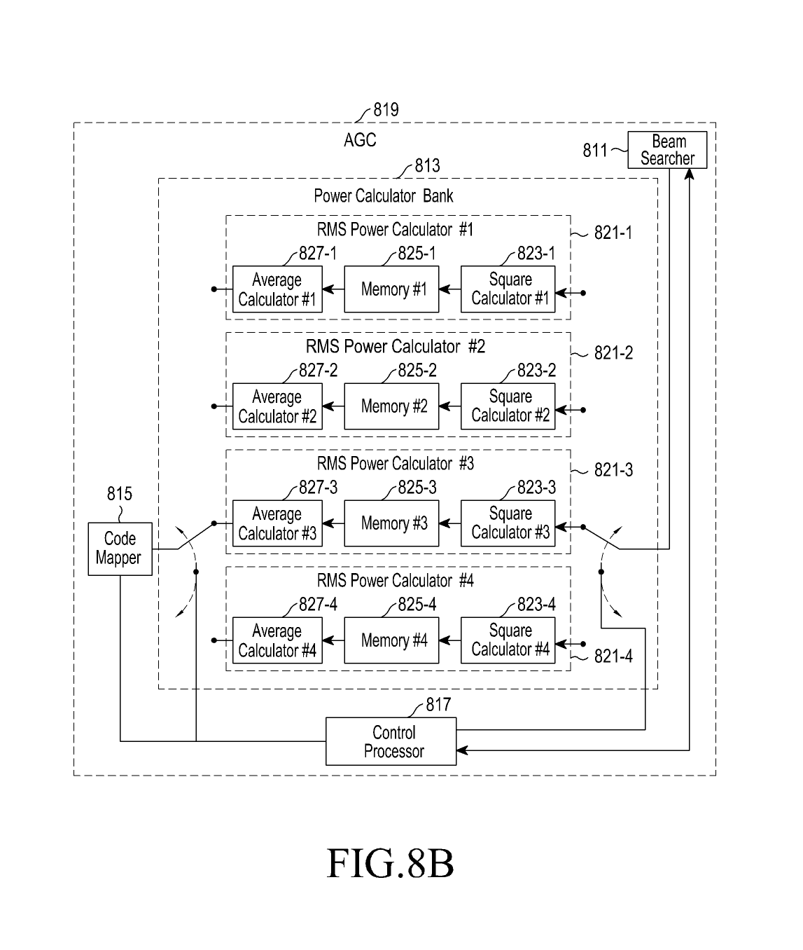

Another example of an inner structure of a terminal in a communication system supporting a beam forming scheme according to an embodiment of the present disclosure has been described with reference to FIGS. 7A and 7B, and still another example of an inner structure of a terminal in a communication system supporting a beam forming scheme according to an embodiment of the present disclosure will be described with reference to FIGS. 8A and 8B.

FIGS. 8A and 8B schematically illustrate still another example of an inner structure of a terminal in a communication system supporting a beam forming scheme according to an embodiment of the present disclosure.

Referring to FIGS. 8A and 8B, a terminal includes an LNA 801, a mixer 803, a VGA 805, an A/D 807, a MODEM 809, and an AGC 819.

The internal structure of the terminal illustrated in FIGS. 8A and 8B corresponds an internal structure of a terminal in a case where a base station supports six beam types, and the six beam types are generated by considering two beam widths, i.e., a first beam width and a second beam width, and four beam directions, i.e., a first beam direction, a second beam direction, a third beam direction, and a fourth beam direction. That is, the base station supports a first beam type which is generated by considering the first beam width and the first beam direction, a second beam type which is generated by considering the first beam width and the second beam direction, a third beam type which is generated by considering the second beam width and the first beam direction, a fourth beam type which is generated by considering the second beam width and the second beam direction, a fifth beam type which is generated by considering the second beam width and the third beam direction, and a sixth beam type which is generated by considering the second beam width and the fourth beam direction.

In the internal structure of the terminal of FIGS. 8A and 8B, the terminal includes a power calculator bank which manages beam directions where an RMS power greater than or equal to a preset threshold RMS power is detected, and beam directions where an RMS power less than the preset threshold RMS power is detected by applying a preset criterion per beam width even though the base station supports six beam types. That is, a terminal in FIGS. 7A and 7B is also a terminal which is applied if a base station supports six beam types, however, it will be understood that the terminal includes a power calculator bank which manages each of the six beam types supported in the base station, so the terminal in FIGS. 7A and 7B is different to the terminal in FIGS. 8A and 8B with respect to a power calculator bank.

A signal received through an antenna is input to the LNA 801, the LNA 801 amplifies the signal received through the antenna according to a preset gain value, and outputs the amplified signal to the mixer 803. The mixer 803 down converts the signal output from the LNA 801 by mixing the amplified signal output from the LNA 801 with a preset frequency signal, and outputs the down converted signal to the VGA 805. The VGA 805 amplifies the signal output from the mixer 803 according to a preset gain value, and outputs the amplified signal to the A/D 807. The A/D 807 generates an I/Q signal by converting the signal output from the VGA 805, i.e., an analog signal to a digital signal, and outputs the I/Q signal to the MODEM 809. The MODEM 809 de-modulates the signal output from the A/D 807 using a preset de-modulation scheme, and outputs the de-modulated signal. The de-modulation scheme is determined according to a modulation scheme used in the base station.

The AGC 819 performs an operation of controlling both the gain value of the LNA 801 and the gain value of the VGA 805. The AGC 819 may control both the gain value of the LNA 801 and the gain value of the VGA 805 according to a beam type used in the base station, may output a control signal for controlling the gain value of the LNA 801 to the LNA 801, and may output a control signal for controlling the gain value of the VGA 805 to the VGA 805.

An operation of storing information on a beam type used in the terminal and an operation of controlling the gain value of the LNA 801 and the gain value of the VGA 805 in the AGC 819 will be described below.

The AGC 819 includes a beam searcher 811, a power calculator bank 813, a control processor 817, and a code mapper 815.

The power calculator bank 813 includes a plurality of RMS power calculators, e.g., four RMS power calculators, for storing the measured instantaneous power based on a preset threshold RMS power per beam width from among beam types. That is, the power calculator bank 813 includes an RMS power calculator #1 821-1 to an RMS power calculator #4 821-4. The number of RMS power calculators included in the power calculator bank 813 may be determined based on the threshold RMS power per beam width from among beam types which the base station may operate, so the number of RMS power calculators is determined to 4 in the power calculator band 813.

The beam searcher 811 measures an instantaneous power of a reference signal output from the MODEM 809 according to a beam type that is applied to a currently received signal. The beam type may be different according to a beam width and a beam direction. In other words, respective beam types may be different from each other according to respective beam widths and beam directions. The beam searcher 811 outputs the measured instantaneous power for the reference signal and related beam information to the control processor 817. The control processor 817 detects information on a plurality of beam types operated in the base station, information on a beam gain per beam type, information on a time interval used per beam type, information on a channel used per beam type, and information on the like, from a broadcast channel which the base station broadcasts.

In an embodiment of the present disclosure, the control processor 817 detects the information on the plurality of beam types operated in the base station, the information on the beam gain per beam type, the information on the time interval used per beam type, the information on the channel used per beam type, and the information on the like, from the broadcast channel. However, it will be understood by those of ordinary skill in the art that the control processor 817 may detect the information on the plurality of beam types operated in the signal transmission apparatus, the information on the beam gain per beam type, the information on the time interval used per beam type, the information on the channel used per beam type, and the like from a channel different from the broadcast channel, from a message, and/or from any suitable source.

The control processor 817 determines an RMS power calculator, in which a power value output from the beam searcher 811 will be stored, from among the RMS power calculator #1 821-1 to the RMS power calculator #4 721-4, according to the measured result output from the beam searcher 811. The control processor 817 selects an RMS power calculator, which will be used for determining both the gain value of the LNA 801 and the gain value of the VGA 805, from among the RMS power calculator #1 821-1 to the RMS power calculator #4 821-4, based on the beam information.

The power calculator bank 813 includes four RMS power calculators, i.e., the RMS power calculator #1 821-1 to the RMS power calculator #4 821-4. Each of the RMS power calculator #1 821-1 to the RMS power calculator #4 821-4 calculates an average power per beam type and stores an instantaneous power. As described above, the power calculator bank 813 may be configured based on the beam width. The number of RMS power calculators included in the power calculator bank 813 may be determined according to the number of beam types which the base station may operate. That is, the number of RMS power calculators included in the power calculator bank 813 is ‘4’ based on the threshold RMS power based on the beam width from among the beam types which the base station may operate.

Meanwhile, each of the RMS power calculator #1 821-1 to the RMS power calculator #4 821-4 includes a square calculator, a memory, and an average calculator. That is, the RMS power calculator #1 821-1 includes a square calculator #1 823-1, a memory #1 825-1, and an average calculator #1 827-1, the RMS power calculator #2 821-2 includes a square calculator #2 823-2, a memory #2 825-2, and an average calculator #2 827-2, the RMS power calculator #3 821-3 includes a square calculator #3 823-3, a memory #3 825-3, and an average calculator #3 827-3, and the RMS power calculator #4 821-4 includes a square calculator #4 823-4, a memory #4 825-4, and an average calculator #4 827-4.

Firstly, the RMS power calculator #1 821-1 will be described below.

The square calculator #1 823-1 calculates an instantaneous power value by squaring a signal strength of the signal output from the MODEM 809, and outputs the instantaneous power value to the memory #1 825-1. The memory #1 825-1 stores the instantaneous power value output from the square calculator #1 823-1. The average calculator #1 827-1 calculates an average power of the instantaneous power values stored during a preset time interval, e.g., T_{WINDOW}.

The RMS power calculator #4 821-4, as the last RMS power calculator, will be described below.

The square calculator #4 823-4 calculates an instantaneous power value by squaring a signal strength of the signal output from the MODEM 809, and outputs the instantaneous power value to the memory #4 825-4. The memory #4 825-4 stores the instantaneous power value output from the square calculator #4 823-4. The average calculator #4 827-4 calculates an average power of the instantaneous power values stored during the preset time interval, e.g., T_{WINDOW}.

The code mapper 815 determines both the gain value of the LNA 801 and the gain value of the VGA 805 based on the average power, calculated in the average calculator #1 827-1 to the average calculator #4 827-4, corresponding to a timing point determined by the control processor 817. The code mapper 815 generates a code value related to each of the gain value of the LNA 801 and the gain value of the VGA 805, and outputs the generated code value to the LNA 801 and the VGA 805.

As illustrated in FIGS. 8A and 8B, it will be noted that the terminal is implemented in order that the power calculator bank 813 includes an RMS power calculator based on a beam width and a threshold RMS power, wherein the RMS power calculator is not based on each of the beam types supported in the base station.

Although the LNA 801, the mixer 803, the VGA 805, the A/D 807, the MODEM 809, and the AGC 819 are illustrated in the terminal in FIGS. 8A and 8B as separate units, it is to be understood that such a configuration is merely for convenience of description. In other words, two or more of the LNA 801, the mixer 803, the VGA 805, the A/D 807, the MODEM 809, and the AGC 819 may be incorporated into a single unit. Further, locations of the LNA 801, the mixer 803, the VGA 805, the A/D 807, the MODEM 809, and the AGC 819 may be changed, and specific units from among these units may be omitted. Although four RMS power calculators, i.e., the RMS power calculator #1 821-1 to the RMS power calculator #4 821-4, are illustrated in the power calculator bank 813 in FIGS. 8A to 8B as separate units, it is to be understood that such a configuration is merely for convenience of description. In other words, two or more of the RMS power calculator #1 821-1 to the RMS power calculator #4 821-4 may be incorporated into a single unit. Although a square calculator, a memory, and an average calculator are illustrated in each of the RMS power calculator #1 821-1 to the RMS power calculator #4 821-4 in FIGS. 8A to 8B as separate units, it is to be understood that such a configuration is merely for convenience of description. In other words, two or more of the square calculator, the memory, and the average calculator may be incorporated into a single unit.

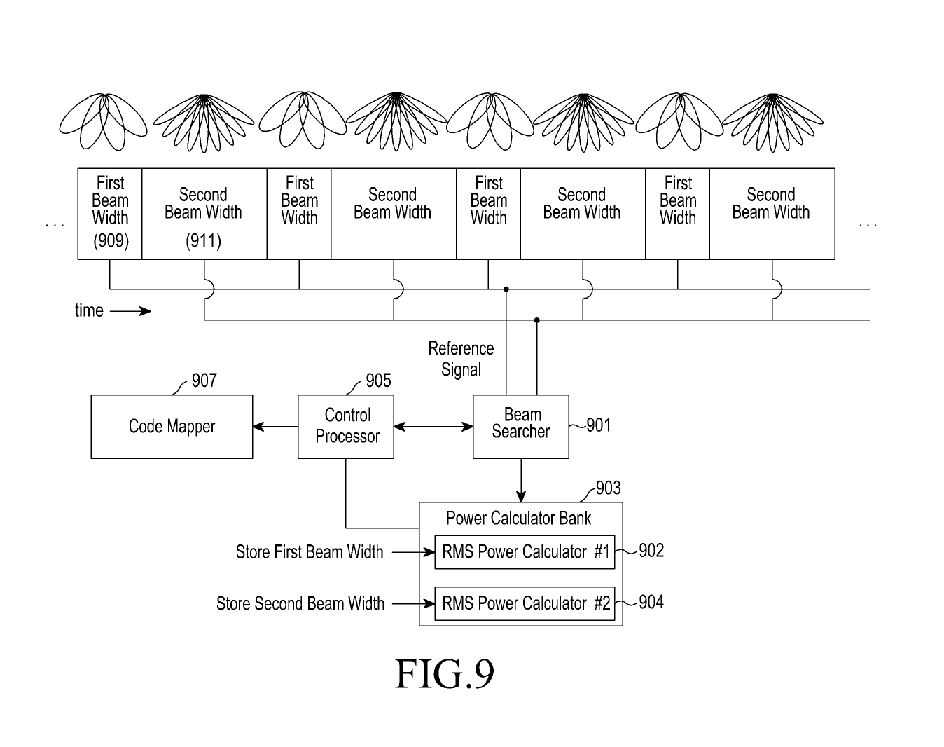

Still another example of an inner structure of a terminal in a communication system supporting a beam forming scheme according to an embodiment of the present disclosure has been described with reference to FIGS. 8A and 8B, and an operation process of an AGC included in a terminal in a communication system supporting a beam forming scheme according to an embodiment of the present disclosure will be described with reference to FIG. 9.

FIG. 9 schematically illustrates an operation process of an AGC included in a terminal in a communication system supporting a beam forming scheme according to an embodiment of the present disclosure.

Referring to FIG. 9, a base station periodically transmits a first beam width signal 909, to which a first beam width is applied, and a second beam width signal 911, to which a second beam width is applied, to a terminal. For convenience, a signal to which the first beam width is applied is called as ‘a first beam width signal’, and a signal to which the second beam width is applied is called as ‘a second beam width signal’.

The base station may previously notify the terminal of information on a length and a timing point of an interval in which a signal to which each beam width is applied is transmitted. The base station may previously notify the terminal of the information on the length and the timing point of the interval in which the signal to which each beam width is applied is transmitted through a broadcast channel or a preset message.

In FIG. 9, illustrates a case in which the base station supports two beam widths, however, it will be understood by those of ordinary skill in the art that an operation process of an AGC in FIG. 9 may be applicable to a case in which the base station supports a beam direction and a combination of a beam width and the beam direction, rather than just the beam width. That is, the operation process of the AGC in FIG. 9 may be applicable for all beam types supported in the base station.

The terminal includes a beam searcher 901, a power calculator bank 903, a control processor 905, and a code mapper 907, and the power calculator bank 903 includes an RMS power calculator #1 902 and an RMS power calculator #2 904.

In a time interval in which the first beam width signal 909 is received, the beam searcher 901 calculates an instantaneous power according to the first beam width signal 909, and outputs the calculated instantaneous power and information of the first beam width signal 909 to the control processor 905. The control processor 905 controls the RMS power calculator #1 902, which is included in the power calculator bank 903, to continuously accumulate an instantaneous power of a first beam width during the preset time interval T_{WINDOW} and to calculate an average power value if needed. The control processor 905 controls the code mapper 905 to determine a gain value of an LNA (not illustrated in FIG. 9) included in the terminal and a gain value of a VGA (not illustrated in FIG. 9) included in the terminal based on the average power value for the first beam width, as calculated by the RMS power calculator #1 902 in a current time interval and following time intervals where a first beam width signal is received.

Upon reaching a time interval where the second beam width signal 911 is received, the beam searcher 901 calculates an instantaneous power of the second beam width signal 911, and outputs the calculated instantaneous power and information on the second beam width signal 911 to the control processor 905.

The control processor 905 controls the RMS power calculator #2 904, which is included in the power calculator bank 903, to continuously accumulate an instantaneous power of the second beam width during the preset time interval T_{WINDOW} and to calculate an average power value if needed. The control processor 905 controls the code mapper 905 to determine both a gain value of the LNA and a gain value of the VGA based on the average power value of the second beam width, as calculated by the RMS power calculator #2 904 in a current time interval and following time intervals where the second beam width signal is received.

As described above, each of related RMS power calculators for the first beam width signal 909 and the second beam width signal 911, i.e., the RMS power calculator #1 902 and the RMS power calculator #2 904, respectively and continuously accumulate an instantaneous power of a related beam width signal, and calculate an average power value.

For example, if the first beam width signal 909 is received, the terminal continuously accumulates an instantaneous power using the RMS power calculator #1 902, and updates an average power value by storing the instantaneous power, which may be used to calculate the updated average power value. The terminal determines a gain value according to a beam type using the updated average power value, and controls the LNA and the VGA based on the determined gain value.

For example, if the second beam width signal 911 is received, the terminal continuously accumulates an instantaneous power using the RMS power calculator #2 904, and updates an average power value by storing the instantaneous power. The terminal determines a gain value according to a beam type using the updated average power value, and controls the LNA and the VGA based on the determined gain value.

That is, the power calculator bank 903 calculates power values for all beam types, according to at least one of a beam width and/or a beam direction, supported in the base station, separately stores each of the power values so that the AGC may flexibly determine a gain value according to a beam type which is applied to a signal to be received.

Although the beam searcher 901, the power calculator bank 903, the control processor 905, and the code mapper 907 are illustrated in the AGC in FIG. 9 as separate units, it is to be understood that such a configuration is merely for convenience of description. In other words, two or more of the beam searcher 901, the power calculator bank 903, the control processor 905, and the code mapper 907 may be incorporated into a single unit. Further, locations of the beam searcher 901, the power calculator bank 903, the control processor 905, and the code mapper 907 may be changed, and specific units from among these units may be omitted. Although two RMS power calculators, i.e., the RMS power calculator #1 902 to the RMS power calculator #2 904, are illustrated in the power calculator bank #903 in FIG. 9 as separate units, it is to be understood that such a configuration is merely for convenience of description. In other words, the RMS power calculator #1 902 and the RMS power calculator #2 904 may be incorporated into a single unit.

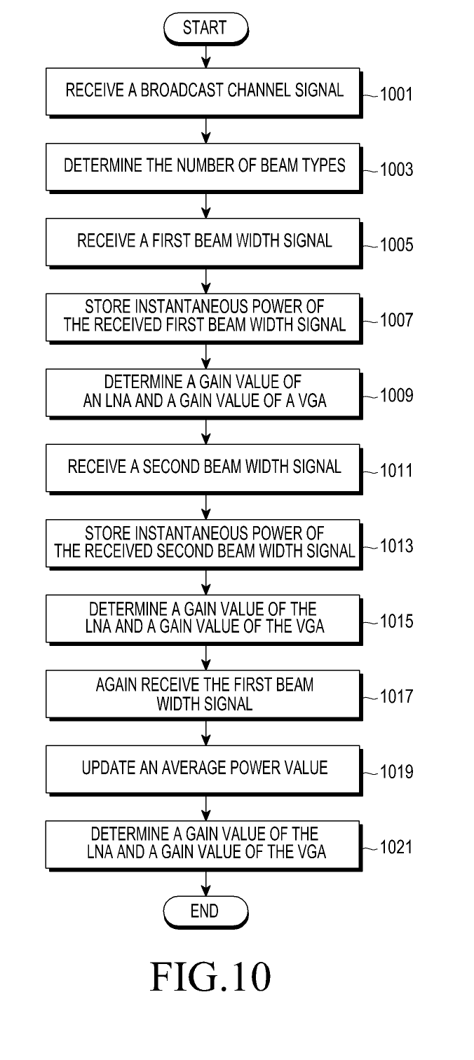

An operation process of an AGC included in a terminal in a communication system supporting a beam forming scheme according to an embodiment of the present disclosure has been described with reference to FIG. 9, and an operation process of a terminal in a communication system supporting a beam forming scheme according to an embodiment of the present disclosure will be described with reference to FIG. 10.

FIG. 10 schematically illustrates an operation process of a terminal in a communication system supporting a beam forming scheme according to an embodiment of the present disclosure.

Referring to FIG. 10, a terminal receives a broadcast channel signal broadcasted from a base station in operation 1001. The broadcast channel signal includes information on at least one of a plurality of beam types, such as information on beam widths and/or beam directions, which are operated by the base station, a beam gain per beam type, a time interval which is used per beam type, and a channel which is used per beam type. Although not illustrated in FIG. 10, the terminal receives the information on at least one of the plurality of beam types which are operated by the base station, the beam gain per beam type, the time interval which is used per beam type, and the channel which is used per beam type from the broadcast channel signal. However, it will be understood by those of ordinary skill in the art that the terminal may receive the information on at least one of the plurality of beam types which are operated by the base station, the beam gain per beam type, the time interval which is used per beam type, and the channel which is used per beam type from other channel signal not the broadcast channel signal or a preset message.

The terminal acquires the information on the beam types which are operated by the base station through the information included in the received broadcast channel signal, and determines a number N of beam types which the terminal will store in operation 1003. As illustrated in FIG. 10, the terminal determines to store power values for two beam types which the base station operates, i.e., a first beam width and a second beam width, and, as illustrated in FIG. 10, a beam type, according to a beam width, is considered. However, it will be understood by those of ordinary skill in the art that a beam type according to a beam direction and/or a combination of the beam width and the beam direction as well as just the beam width may be considered.

The terminal receives a first beam width signal, to which a first beam width is applied, in operation 1005. The terminal measures an instantaneous power of the received first beam width signal using an RMS power calculator #1 corresponding to the first beam width signal, and stores the measured instantaneous power in operation 1007. The terminal determines a gain value of an LNA and a gain value of a VGA using average power calculated according to the instantaneous power measured for the received first beam width signal in operation 1009. The terminal receives a signal to which a second beam width is applied in operation 1011. The terminal stores an instantaneous power measured for the received second beam width signal in an RMS power calculator #2 corresponding to the second beam width in operation 1013. The terminal determines a gain value of the LNA and a gain value of the VGA using an average power calculated according to the instantaneous power measured for the received second beam width signal in operation 1015.

The terminal again receives the first beam width signal in operation 1017. The terminal continuously accumulates an instantaneous power in the RMS power calculator #1 corresponding to the first beam width and updates an average power value in operation 1019. The terminal determines a gain value of the LNA and a gain value of the VGA in operation 1021, according to a beam type using the updated average power value, and the terminal controls the LNA and the VGA based on the determined gain value.

Although not illustrated in FIG. 10, upon again receiving the second beam width signal, the terminal controls the LNA and the VGA using an average power value accumulated in the RMS power calculator #1 corresponding to the second beam width like a case where the terminal receives the first beam width signal.

In FIG. 10, a base station uses a first beam width and a second beam width by limiting beam types to be different from each other according to only a beam width. However, it will be understood by those of ordinary skill in the art that beam types may be different from each other according to, and that the base station may generate a beam type based on, a beam direction, a combination of the beam width and the beam direction, and the like as well as the beam width. In this case, RMS power calculators may be used based on the number of beam types used in the base station.

Although FIG. 10 illustrates an operation process of a terminal in a communication system supporting a beam forming scheme according to an embodiment of the present disclosure, various changes could be made to FIG. 10. For example, although illustrated as a series of operations, according to an embodiment of the present disclosure, various operations in FIG. 10 could overlap, occur in parallel, occur in a different order, and/or occur multiple times.

It can be appreciated that a method and apparatus for controlling a gain in a communication system supporting a beam forming scheme according to an embodiment of the present disclosure may be implemented by hardware, software and/or a combination thereof. The software may be stored in a non-volatile storage, for example, an erasable or re-writable Read Only Memory (ROM), a memory, for example, a Random Access Memory (RAM, a memory chip, a memory device, or a memory Integrated Circuit (IC), or an optically or magnetically recordable non-transitory machine-readable, e.g., computer-readable, storage medium, e.g., a Compact Disk (CD), a Digital Versatile Disk (DVD), a magnetic disk, or a magnetic tape.

A method and apparatus for controlling a gain in a communication system supporting a beam forming scheme according to an embodiment of the present disclosure may be implemented by a computer or a mobile terminal that includes a controller and a memory, and the memory may be an example of a non-transitory machine-readable, e.g., computer-readable, storage medium suitable to store a program or programs including instructions for implementing various embodiments of the present disclosure.

The present disclosure may include a program including code for implementing the apparatus and method as defined by the appended claims, and a non-transitory machine-readable, e.g., computer-readable, storage medium storing the program. The program may be electronically transferred via any media, such as communication signals, which are transmitted through wired and/or wireless connections, and the present disclosure may include their equivalents.

As is apparent from the foregoing description, an embodiment of the present disclosure enables control of a gain in a communication system supporting a beam forming scheme.

An embodiment of the present disclosure enables control of a gain in a case where at least two beam types are used in a communication system supporting a beam forming scheme.

An embodiment of the present disclosure enables automatic control of a gain corresponding to a beam type in a case where at least two beam types are used in a communication system supporting a beam forming scheme.

An embodiment of the present disclosure enables automatic control of a gain by considering signal strength for an optimal beam type in a case where at least two beam types are used in a communication system supporting a beam forming scheme.

While the present disclosure has been shown and described with reference to various embodiments thereof, it will be understood by those skilled in the art that various changes in form and details may be made therein without departing from the spirit and scope of the present disclosure as defined by the appended claims and their equivalents.

What is claimed is:

1. A signal reception apparatus in a communication system supporting a beam forming scheme, the signal reception apparatus comprising:
a Low Noise Amplifier (LNA) configured to generate a second signal by amplifying a first signal according to a first gain value;
a Variable Gain Amplifier (VGA) configured to generate a third signal by amplifying the second signal according to a second gain value; and
an Automatic Gain Controller (AGC) configured to control the first gain value and the second gain value by considering a plurality of beam types supported in a signal transmission apparatus.

2. The signal reception apparatus of claim 1, wherein the AGC comprises:
a beam searcher configured to detect a beam type applied to the third signal, from among the plurality of beam types;
a power calculator bank configured to calculate Root Mean Square (RMS) power of the third signal corresponding to the detected beam type; and
a code mapper configured to determine the first gain value and the second gain value corresponding to the RMS power calculated in the power calculator bank.

3. The signal reception apparatus of claim 2, wherein the power calculator bank includes a number of RMS power calculators equal to a number of the beam types, and
wherein each of the RMS power calculators calculates an RMS power of the third signal corresponding to a related beam type.

4. The signal reception apparatus of claim 3, wherein each of the RMS power calculators comprises:
a square calculator configured to calculate an instantaneous power value of the third signal; and
an average calculator configured to calculate average power of instantaneous power values calculated in the square calculator during a time interval.

5. The signal reception apparatus of claim 4, wherein each of the RMS power calculators further comprises a memory configured to store the instantaneous power values calculated in the square calculator during the time interval.

6. The signal reception apparatus of claim 3, wherein the AGC further comprises a switch configured to switch the third signal to an RMS power calculator configured to calculate an RMS power of the beam type detected in the beam searcher from among the plurality of the RMS power calculators.

7. The signal reception apparatus of claim 1, wherein the AGC further comprises a control processor configured to detect at least one of information on the plurality of beam types, information on a beam gain of each of the plurality of beam types, information on a time interval in which each of the plurality of beam types is used, and information on a channel in which each of the plurality of beam types is used.

8. The signal reception apparatus of claim 6, wherein the control processor is further configured to detect at least one of the information on the plurality of beam types, the information on the beam gain of each of the plurality of beam types, the information on the time interval in which each of the plurality of beam types is used, and the information on the channel in which each of the plurality of beam types is used through at least one of a broadcast channel and a message.

9. The signal reception apparatus of claim 2, wherein the third signal is a reference signal.

10. The signal reception apparatus of claim 1, wherein each of the plurality of beam types is determined by considering at least one of a beam width, a beam direction, and a combination of the beam width and the beam direction.

11. A signal reception apparatus in a communication system supporting a beam forming scheme, the signal reception apparatus comprising:
a Low Noise Amplifier (LNA) configured to generate a second signal by amplifying a first signal according to a first gain value;
a mixer configured to generate a third signal by mixing the second signal with a frequency signal;
a Variable Gain Amplifier (VGA) configured to generate a fourth signal by amplifying the third signal according to a second gain value;
an analog/digital converter configured to generate a fifth signal by digital converting the fourth signal;
a MOdulator/DEModulator (MODEM) configured to generate a sixth signal by de-modulating the fifth signal using a de-modulation scheme corresponding to a modulation scheme used in a signal transmission apparatus; and
an Automatic Gain Controller (AGC) configured to control the first gain value and the second gain value by considering a plurality of beam types supported in the signal transmission apparatus.

12. The signal reception apparatus of claim 11, wherein the AGC comprises:
a beam searcher configured to detect a beam type applied to the sixth signal from among the plurality of beam types;
a power calculator bank configured to calculate Root Mean Square (RMS) power of the sixth signal corresponding to the detected beam type; and
a code mapper configured to determine the first gain value and the second gain value corresponding to the RMS power calculated in the power calculator bank.

13. The signal reception apparatus of claim 12, wherein the power calculator bank includes a number of RMS power calculators equal to a number of the beam types, and
wherein each of the RMS power calculators calculates an RMS power of the sixth signal corresponding to a related beam type.

14. The signal reception apparatus of claim 13, wherein each of the RMS power calculators comprises:
a square calculator configured to calculate an instantaneous power value of the sixth signal; and
an average calculator configured to calculate average power of instantaneous power values calculated in the square calculator during a time interval.

15. The signal reception apparatus of claim 14, wherein each of the RMS power calculators further comprises a memory configured to store the instantaneous power values calculated in the square calculator during the time interval.

16. The signal reception apparatus of claim 13, wherein the AGC further comprises a switch configured to switch the sixth signal to an RMS power calculator configured to calculate an RMS power of the beam type detected in the beam searcher from among the plurality of the RMS power calculators.

17. The signal reception apparatus of claim 11, wherein the AGC further comprises a control processor configured to detect at least one of information on the plurality of beam types, information on a beam gain of each of the plurality of beam types, information on a time interval in which each of the plurality of beam types is used, and information on a channel in which each of the plurality of beam types is used.

18. The signal reception apparatus of claim 16, wherein the control processor is further configured to detect at least one the information on the plurality of beam types, the information on the beam gain of each of the plurality of beam types, the information on the time interval in which each of the plurality of beam types is used, and the information on the channel in which each of the plurality of beam types is used through at least one of a broadcast channel and a message.

19. The signal reception apparatus of claim 12, wherein the sixth signal is a reference signal.

20. The signal reception apparatus of claim 11, wherein each of the plurality of beam types is determined by considering at least one of a beam width, a beam direction, and a combination of the beam width and the beam direction.

21. An operation method of a signal reception apparatus in a communication system supporting a beam forming scheme, the operation method comprising:
determining a first gain value and a second gain value by considering a plurality of beam types supported in a signal transmission apparatus;
generating a second signal by amplifying a first signal according to the first gain value; and
generating a third signal by amplifying the second signal according to the second gain value.

22. The operation method of claim 21, wherein the determining of the first gain value and the second gain value by considering the plurality of beam types supported in the signal transmission apparatus comprises:
detecting a beam type applied to the third signal from among the plurality of beam types;
calculating Root Mean Square (RMS) power of the third signal corresponding to the detected beam type; and
determining the first gain value and the second gain value corresponding to the calculated RMS power.

23. The operation method of claim 22, wherein the calculating of the RMS power of the third signal corresponding to the detected beam type comprises calculating the RMS power of the third signal corresponding to each of the beam types.

24. The operation method of claim 23, wherein the calculating of the RMS power of the third signal corresponding to each of the beam types comprises:
calculating an instantaneous power value of the third signal; and
calculating an average power of instantaneous power values during a time interval.

25. The operation method of claim 24, wherein the calculating of the RMS power of the third signal corresponding to each of the beam types comprises storing the instantaneous power values calculated during the time interval.

26. The operation method of claim 21, further comprising:
detecting at least one of information on the plurality of beam types, information on a beam gain of each of the plurality of beam types, information on a time interval in which each of the plurality of beam types is used, and information on a channel in which each of the plurality of beam types is used.

27. The operation method of claim 26, wherein the detecting of at least one of the information on the plurality of beam types, the information on the beam gain of each of the plurality of beam types, the information on the time interval in which each of the plurality of beam types is used, and the information on the channel in which each of the plurality of beam types is used comprises detecting at least one of the information on the plurality of beam types, the information on the beam gain of each of the plurality of beam types, the information on the time interval in which each of the plurality of beam types is used, and the information on the channel in which each of the plurality of beam types is used through at least one of a broadcast channel and a message.

28. The operation method of claim 22, wherein the third signal is a reference signal.

29. The operation method of claim 21, wherein each of the plurality of beam types is determined by considering at least one of a beam width, a beam direction, and a combination of the beam width and the beam direction.

30. An operation method of a signal reception apparatus in a communication system supporting a beam forming scheme, the operation method comprising:
determining a first gain value and a second gain value by considering a plurality of beam types supported in a signal transmission apparatus;
generating a second signal by amplifying a first signal according to the first gain value;
generating a third signal by mixing the second signal with a frequency signal;
generating a fourth signal by amplifying the third signal according to a second gain value;
generating a fifth signal by digital converting the fourth signal; and
generating a sixth signal by de-modulating the fifth signal using a de-modulation scheme corresponding to a modulation scheme used in the signal transmission apparatus.

31. The operation method of claim 30, wherein the determining of the first gain value and the second gain value by considering the plurality of beam types supported in the signal transmission apparatus comprises:
detecting a beam type applied to the sixth signal from among the plurality of beam types;
calculating Root Mean Square (RMS) power of the sixth signal corresponding to the detected beam type; and
determining the first gain value and the second gain value corresponding to the calculated RMS power.

32. The operation method of claim 31, wherein the calculating of the RMS power of the sixth signal corresponding to the detected beam type comprises calculating the RMS power of the sixth signal corresponding to each of the beam types.

33. The operation method of claim 32, wherein the calculating of the RMS power of the sixth signal corresponding to the detected beam type comprises:
calculating an instantaneous power value of the sixth signal; and
calculating average power of instantaneous power values during a time interval.

34. The operation method of claim 32, wherein the calculating of the RMS power of the sixth signal corresponding to the detected beam type further comprises storing the instantaneous power values calculated during the time interval.

35. The operation method of claim 30, further comprising:
detecting at least one of information on the plurality of beam types, information on a beam gain of each of the plurality of beam types, information on a time interval in which each of the plurality of beam types is used, and information on a channel in which each of the plurality of beam types is used.

36. The operation method of claim 35, wherein the detecting of at least one of the information on the plurality of beam types, the information on the beam gain of each of the plurality of beam types, the information on the time interval in which each of the plurality of beam types is used, and the information on the channel in which each of the plurality of beam types is used comprises detecting at least one of the information on the plurality of beam types, the information on the beam gain of each of the plurality of beam types, the information on the time interval in which each of the plurality of beam types is used, and the information on the channel in which each of the plurality of beam types is used through at least one of a broadcast channel and a message.

37. The operation method of claim 31, wherein the sixth signal is a reference signal.

38. The operation method of claim 30, wherein each of the plurality of beam types is determined by considering at least one of a beam width, a beam direction, and a combination of the beam width and the beam direction.
